(19) United States
(12) Patent Application Publication
(10) Pub. No.: US 2019/0378699 A1
(43) Pub. Date: Dec. 12, 2019

(54) METHODS AND APPARATUS FOR MAGNETRON ASSEMBLIES IN SEMICONDUCTOR PROCESS CHAMBERS

(71) Applicant: APPLIED MATERIALS, INC., Santa Clara, CA (US)

(72) Inventors: RONGJUN WANG, DUBLIN, CA (US); XIAODONG WANG, SAN JOSE, CA (US); WEI WANG, Santa Clara, CA (US)

(21) Appl. No.: 16/425,189

(22) Filed: May 29, 2019

Related U.S. Application Data
(60) Provisional application No. 62/681,790, filed on Jun. 7, 2018.

(51) Int. Cl. H01J 37/34; H01L 21/02

(52) U.S. Cl. CPC H01J 37/3405; H01L 21/02266; H01J 37/3452; H01J 37/3441; H01L 21/02631

(57) ABSTRACT

An apparatus for processing semiconductors that comprises a process chamber with multiple cathodes disposed in a top adapter assembly. The multiple cathodes having magnetron assemblies that comprise a shunt plate for supporting the magnetron assembly, a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly, and an open loop magnetic pole arc assembly coupled to the shunt plate surrounding at least a portion of the center magnetic pole without intersecting with the linear magnetic pole. The magnetron assemblies are orientated such that an opening of the open loop magnetic pole arc assembly is oriented towards an outer wall of the shield.

### CROSS-REFERENCE TO RELATED APPLICATIONS

This application claims benefit of U.S. provisional patent application Ser. No. 62/681,790, filed Jun. 7, 2018 which is herein incorporated by reference in its entirety.

### FIELD

Embodiments of the present principles generally relate to semiconductor process chambers.

### BACKGROUND

Plasma is used in semiconductor processing to deposit thin layers of material onto a substrate in a process known as sputtering. Plasma sputtering may be accomplished using either DC sputtering or RF sputtering. Plasma sputtering typically includes a magnetron positioned at the back of the sputtering target to project a magnetic field into the processing space to increase the density of the plasma and enhance the sputtering rate. Multi-cathode processing chambers use multiple sputtering targets that are often closely spaced to increase the number of cathodes in a single chamber. The inventors have observed that heavy material deposits can form on the process kit as the cathodes are spaced closer to the process kit shields, causing peeling and contamination.

Thus, the inventors have provided improved methods and apparatus for magnetrons in semiconductor chambers.

### SUMMARY

Methods and apparatus provide enhanced magnetrons for semiconductor chambers to reduce/prevent excess deposition on shield walls which lead to peeling and contamination.

In some embodiments, a magnetron assembly comprises a shunt plate for supporting the magnetron assembly; a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly; and an open loop magnetic pole arc assembly coupled to the shunt plate surrounding at least a portion of the center magnetic pole without intersecting with the linear magnetic pole.

In some embodiments, the magnetron assembly may further comprise wherein the open loop magnetic pole arc assembly has an arc length of approximately 180 degrees to approximately 350 degrees, wherein the magnetron assembly is in a cathode of a process chamber, wherein the cathode is at least one of a plurality of cathodes in a multi-cathode process chamber, wherein the magnetron assembly is installed in a process chamber with an open portion of the open loop magnetic pole arc assembly in proximity of an outer wall of a shield within the process chamber, wherein the loop magnetic pole assembly has an even distribution of magnets, wherein the open loop magnetic pole arc assembly has an even distribution of magnets, wherein at least a portion of the open loop magnetic pole arc assembly or the loop magnetic pole assembly is made of a ferromagnetic material, wherein a first width of the open loop magnetic pole arc assembly and a second width of the loop magnetic pole are approximately equal, wherein a first distance between the loop magnetic pole and the open loop magnetic pole arc assembly and a second distance between the open loop magnetic pole arc assembly and the center magnetic pole are approximately equal, wherein a third distance between a first end of the open loop magnetic pole arc assembly and the linear magnetic pole and a fourth distance from a second end of the open loop magnetic pole arc assembly and the linear magnetic pole are approximately equal, wherein the loop magnetic pole has a first constant radius about a center point of the center magnetic pole and the open loop magnetic pole arc assembly has a second constant radius about a center point of the center magnetic pole, the first constant radius greater than the second constant radius, and/or wherein a first distance between the loop magnetic pole and the open loop magnetic pole arc assembly and a second distance between the open loop magnetic pole arc assembly and the center magnetic pole are different.

In some embodiments, an apparatus for processing semiconductors comprises a process chamber with a chamber body and a top adapter assembly that form an internal volume and at least one cathode disposed in the top adapter assembly, the at least one cathode having a magnetron assembly configured to produce a magnetic field with a reduced magnetic field strength for a portion of the magnetic field that is in close proximity to a wall of the internal volume.

In some embodiments, the magnetron may further comprise a shunt plate for supporting the magnetron assembly; a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly; and an open loop magnetic pole arc assembly coupled to the shunt plate surrounding at least a portion of the center magnetic pole without intersecting with the linear magnetic pole, wherein the magnetron assembly is configured to be orientated such that an opening of the open loop magnetic pole arc assembly is oriented towards the wall of the internal volume; wherein the open loop magnetic pole arc assembly has an arc length of approximately 180 degrees to approximately 350 degrees; wherein a first width of the open loop magnetic pole arc assembly and a second width of the loop magnetic pole are approximately equal; and/or wherein a first distance between the loop magnetic pole and the open loop magnetic pole arc assembly and a second distance between the open loop magnetic pole arc assembly and the center magnetic pole are different.

In some embodiments, a cathode assembly may comprise a magnetron assembly configured to produce a magnetic field with a reduced magnetic field strength for a portion of the magnetic field and configured to be oriented such that the portion of the magnetic field with the reduced magnetic field strength is in close proximity to a wall of an internal volume of a process chamber when installed.

In some embodiments, the cathode assembly may further comprise a magnetron assembly with a shunt plate for supporting the magnetron assembly; a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly; and an open loop magnetic pole arc assembly coupled to the shunt plate surrounding at least a portion of the center magnetic pole without intersecting with the linear magnetic pole, wherein the cathode assembly is configured to be installed in a process chamber such that the magnetron assembly is orientated with an opening of the open loop magnetic pole arc assembly towards an outer wall of the process chamber.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a schematic view of a multiple cathode process chamber in accordance with some embodiments of the present principles.

FIG. 2 depicts a top view of a top adapter assembly of the multiple cathode processing chamber of FIG. 1 in accordance with some embodiments of the present principles.

FIG. 3 depicts a bottom view of a top adapter assembly in accordance with some embodiments of the present principles.

FIG. 4 is a bottom view of a magnetron in accordance with some embodiments of the present principles.

FIG. 5 is an isometric view of the magnetron illustrated in FIG. 4 in accordance with some embodiments of the present principles.

FIG. 6 is a view of a target showing erosion when used in conjunction with the magnetron of FIG. 4 in accordance with some embodiments of the present principles.

FIG. 7 is an isometric view of a target showing erosion when used in conjunction with the magnetron of FIG. 4 and oriented outwards of a process chamber internal volume in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Multi-cathode process chambers allow greater flexibility in the types of processing that can be accomplished in a single chamber. The cathodes are generally spaced around the top portion of an inner processing volume of the process chamber and may operate with DC power or RF power depending on the type of target material. As more cathodes are incorporated into the process chamber, the cathodes become increasingly closer to the walls of the process kit or shields inside the process chamber. The inventors have found that with such close proximity, the targets may deposit excess material on the shield walls which can lead to peeling and contamination in the process chamber. The detrimental effects are particularly profound when using tantalum pasting techniques to prevent arcing after magnesium oxide depositions. The inventors have also found that by using a magnetron assembly in the cathodes with an open loop magnetic pole arc assembly, the deposition of target material may be advantageously reduced in proximity of the open portion of the open loop magnetic pole arc assembly. By orienting the magnetron assembly such that the open portion of the open loop magnetic pole arc assembly is nearest the shield wall, the amount of target material deposited on the shield wall is beneficially reduced. The inventors have also found that the rate of deposition nearest the wall may be adjusted by adjusting the arc length of the open loop magnetic pole arc assembly within the magnetron assembly. Although some embodiments incorporate the present principles in multi-cathode process chambers, the present principles may also be applied to magnetron assemblies in other environments where reduction of target deposition in a particular direction is advantageous.

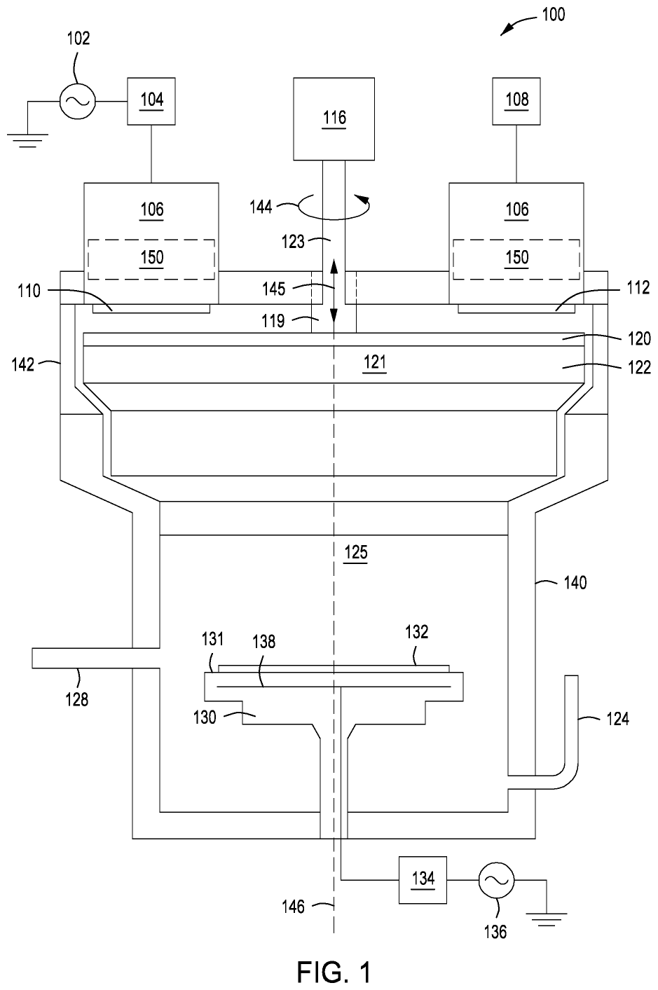

In FIG. 1, a multiple cathode PVD chamber (e.g., process chamber 100) includes a plurality of cathodes 106 having a corresponding plurality of targets (at least one dielectric target 110 and at least one metallic target 112), (for example, 6 cathodes in a 3 RF×3 DC alternating configuration) attached to a chamber body 140 (for example, via a top adapter assembly 142). The cathodes 106 contain magnetrons 150 to help direct plasma during pasting and/or deposition processes. Other RF/DC cathode configurations can also be used such as 1×1, 2×2, 4×4, 5×5, etc. The numbers indicate a ratio of RF powered cathodes to DC powered cathodes. In some embodiments the RF and DC cathodes are alternated in the top adapter assembly 142. When multiple RF cathodes are used, the operating frequencies may be offseted to reduce any interference during deposition processes. For example, in a three RF cathode configuration, the first RF cathode may be operated at a frequency of 13.56 MHz, the second RF cathode is operated at a frequency of 13.66 MHz (+100 kHz), and the third RF cathode is operated at a frequency of 13.46 MHz (−100 kHz). The offset does not need to be +/−100 kHz. The offset can be chosen based on cross-talk prevention for a given number of cathodes.

An RF cathode is typically used with the dielectric target 110 for dielectric film deposition on a substrate. For example, a magnesium oxide (MgO) target can be sputtered using an RF cathode. A DC cathode is typically used with the metallic target 112 for pasting after the dielectric film deposition on the wafer. For example, a tantalum (Ta) target can be sputtered using a DC cathode to paste a chamber after depositing MgO. The pasting reduces the chance of particle formation and defects in the deposition film. Having a process chamber with RF and DC cathodes allows for faster production of wafers because the pasting and dielectric deposition can be done in one chamber. In some embodiments, the metallic target 112 may be formed of a metal such as, for example, tantalum, aluminum, titanium, molybdenum, tungsten, and/or magnesium. The dielectric target 110 may be formed of a metal oxide such as, for example, titanium oxide, titanium magnesium oxide, and/or tantalum magnesium oxide. However, other metals and/or metal oxides may alternatively be used.

The process chamber 100 also includes a substrate support 130 to support a substrate 132. The process chamber 100 includes an opening (not shown) (e.g., a slit valve) through which an end effector (not shown) may extend to place the substrate 132 onto lift pins (not shown) for lowering the substrate 132 onto a support surface 131 of the substrate support 130. In some embodiments shown in FIG. 1, a target 110, 112 is disposed substantially parallel with respect to the support surface 131. The substrate support 130 includes a biasing source 136 coupled to a bias electrode 138 disposed in the substrate support 130 via a matching network 134. The top adapter assembly 142 is coupled to an upper portion of the chamber body 140 of the process chamber 100 and is grounded. A cathode 106 can have a DC power source 108 or an RF power source 102 and an associated magnetron 150. In the case of the RF power source 102, the RF power source 102 is coupled to a cathode 106 via an RF matching network 104.

A shield 121 is rotatably coupled to the top adapter assembly 142 and is shared by the cathodes 106. In some embodiments, the shield 121 includes a shield body 122 and a shield top 120. In other embodiments, the shield 121 has aspects of the shield body 122 and the shield top 120 integrated into one unitary piece. Depending on the number of targets that need to be sputtered at the same time, the shield 121 can have one or more holes to expose a corresponding one or more targets. The shield 121 limits or eliminates cross-contamination between the plurality of targets 110,112. The shield 121 is rotationally coupled to the top adapter assembly 142 via a shaft 123. The shaft 123 is attached to the shield 121 via a coupler 119.

An actuator 116 is coupled to the shaft 123 opposite the shield 121. The actuator 116 is configured to rotate the shield 121, as indicated by arrow 144, and move the shield 121 up and down in the vertical direction along the central axis 146 of the process chamber 100, as indicated by arrow 145. During processing, the shield 121 is raised to an upward position. The raised position of the shield 121 exposes targets used during a processing step and also shields targets not used during the processing step. The raised position also grounds the shield for RF processing steps. In some embodiments, the process chamber 100 further includes a process gas supply 128 to supply a process gas to an internal volume 125 of the process chamber 100. The process chamber 100 may also include an exhaust pump 124 fluidly coupled to the internal volume 125 to exhaust the process gas from the process chamber 100. In some embodiments, for example, the process gas supply 128 may supply oxygen to the internal volume 125 after the metallic target 112 has been sputtered.

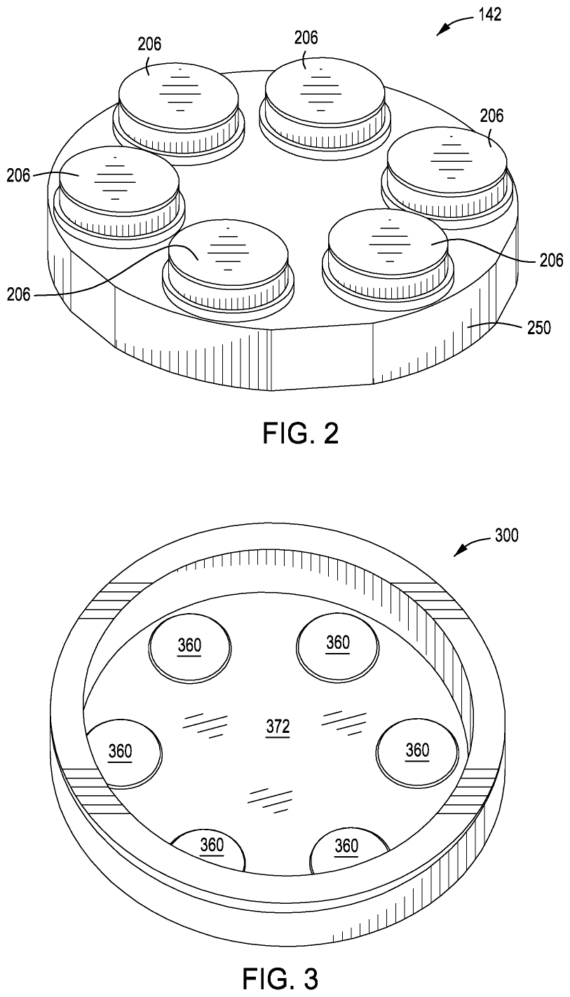

FIG. 2 depicts a top view of the top adapter assembly 142 for some embodiments of the process chamber 100 in FIG. 1. The top adapter assembly 142 includes, for example, an adapter 250 and, for example, 6 cathodes 206. The top adapter assembly 142 can include more or less numbers of cathodes 206. The cathodes 206 contain the magnetrons 150 that help to direct the plasma during processing. The targets for the cathodes 206 are depicted in FIG. 3 which is a bottom view 300 of the top adapter assembly 142 in accordance with some embodiments. An inner bottom surface 372 of the adapter 250 of the top adapter assembly 142 is illustrated. In the example, six targets 360 are shown. Below the targets are the magnetrons 150. In some embodiments, the targets 360 are surrounded and/or covered by a process shield (not shown) such as the shield 121 (see FIG. 1) to prevent deposition on the interior walls of the process chamber 100. As can be seen from FIG. 3, as the number of cathodes increases for process chamber, the targets 360 are spread outward closer towards the walls of the process chamber 100. Since the process kit shields are between the targets 360 and the walls of the process chamber 100, the targets 360 are even closer to the process kit shields. The inventors have found that the close proximity of the shields during metallic deposition or pasting causes excess deposition on the shield areas closest to the targets 360. The excess deposition on the shield leads to peeling of the deposited material and may cause contamination of a substrate and/or the process chamber. The inventors have found that the peeling was especially present when pasting tantalum after an MgO deposition.

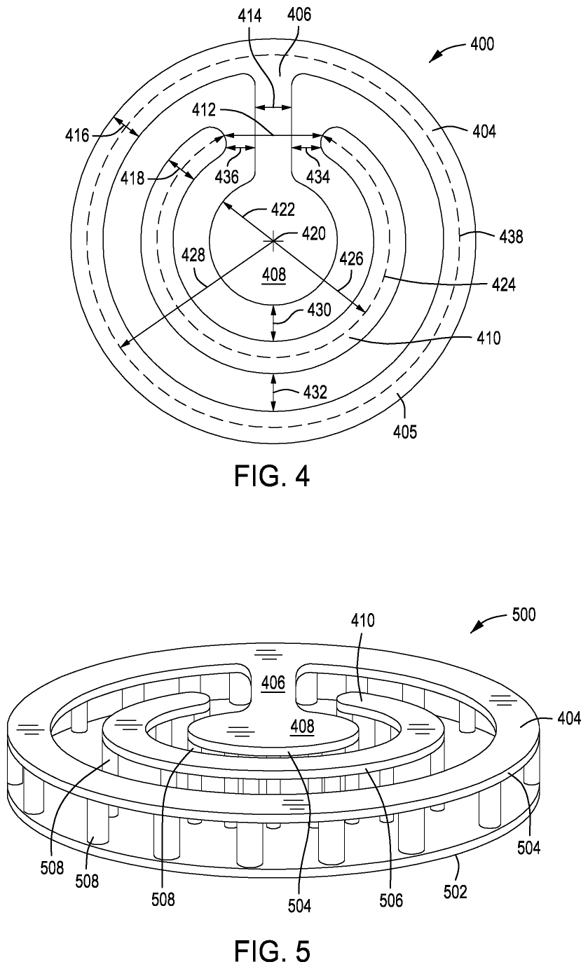

FIG. 4 is a bottom view 400 of a magnetron assembly 402 in accordance with some embodiments. The magnetron assembly 402 includes a loop magnetic pole assembly 404 with a loop magnetic pole 405 (outer loop of the loop magnetic pole assembly 404), a linear magnetic pole 406 and a center magnetic pole 408. The magnetron assembly 402 also includes an open loop magnetic pole arc assembly 410 surrounding the center magnetic pole 408. In some embodiments, the open loop magnetic pole arc assembly 410 may be adjusted to create a greater or smaller arc length 424 around the center magnetic pole 408. By adjusting the arc length 424 to increase an opening 412 of the open loop magnetic pole arc assembly 410, the inventors have found that the amount of material deposited by a target nearest the opening 412 may be decreased. The arc length 424 of the open loop magnetic pole arc assembly 410 may range from approximately 180 degrees to approximately 350 degrees. Orienting the opening 412 towards the shield 121, for example, allows for decreased target material to be deposited on the shield 121 nearest the opening 412, reducing deposition buildup and/or peeling.

A width 416 of the loop magnetic pole 405 may be the same as a width 414 of the linear magnetic pole 406 or different. The width 416 of the loop magnetic pole 405 may be constant or change through the loop magnetic pole 405. The center magnetic pole 408 may have a constant radius 422 about a center point 420 or a changing radius such as, for example, a teardrop shape. A width 418 of the open loop magnetic pole arc assembly 410 may be constant or change through the arc length 424 of the open loop magnetic pole arc assembly 410. A radius 426 of the open loop magnetic pole arc assembly 410 about the center point 420 may be constant or change throughout the arc length 424 (e.g., parabolic shape). A radius 428 of the loop magnetic pole 405 may be constant or change through a loop length 438 about the center point 420. A distance 430 between the open loop magnetic pole arc assembly 410 and the center magnetic pole 408 may be constant throughout the arc length 424 or change throughout the arc length 424. A distance 432 between the loop magnetic pole 405 and the open loop magnetic pole arc assembly 410 may be constant or change throughout the arc length 424. A first distance 434 between a first end of the open loop magnetic pole arc assembly 410 and the linear magnetic pole 406 may be approximately the same as a second distance 436 between a second end of the open loop magnetic pole arc assembly 410 or different.

FIG. 5 is an isometric view 500 of the magnetron assembly 402 illustrated in FIG. 4 in accordance with some embodiments. The loop magnetic pole assembly 404 and the open loop magnetic pole arc assembly 410 are mounted on a shunt plate 502. The shunt plate 502 also serves a structural base for the magnetron assembly. The loop magnetic pole assembly 404 and the open loop magnetic pole arc assembly 410 include a plurality of magnets 508 interposed between the shunt plate 502 and a loop magnetic pole piece 504 and an open loop magnetic pole piece 506. The plurality of magnets 508 does not need to be distributed along the length of the loop magnetic pole piece 504 or the open loop magnetic pole piece 506 or does not need to be distributed evenly along the length of the loop magnetic pole piece 504 or the open loop magnetic pole piece 506. For example, the number and/or distribution of the plurality of magnets 508 may be adjusted to change the magnetic field strength and/or facilitate improved target lifetime and/or deposition uniformity. Spacers (not shown) may be used in place of magnets to provide support in lieu of the magnets. The center magnetic pole 408 may be comprised of multiple magnets or a single magnet.

The loop magnetic pole piece 504 and the open loop magnetic pole piece 506 may be fabricated from a ferromagnetic material, such as, for example, 400-series stainless steel or other suitable materials. The magnetic strengths of the loop magnetic pole assembly 404 and the open loop magnetic pole arc assembly 410 may be the same or different. The polarity within an assembly may be the same (e.g., north or south), but the polarity may be opposite between assemblies (e.g., loop magnetic pole assembly north and open loop magnetic pole arc assembly south or loop magnetic pole assembly south and open loop magnetic pole arc assembly north).

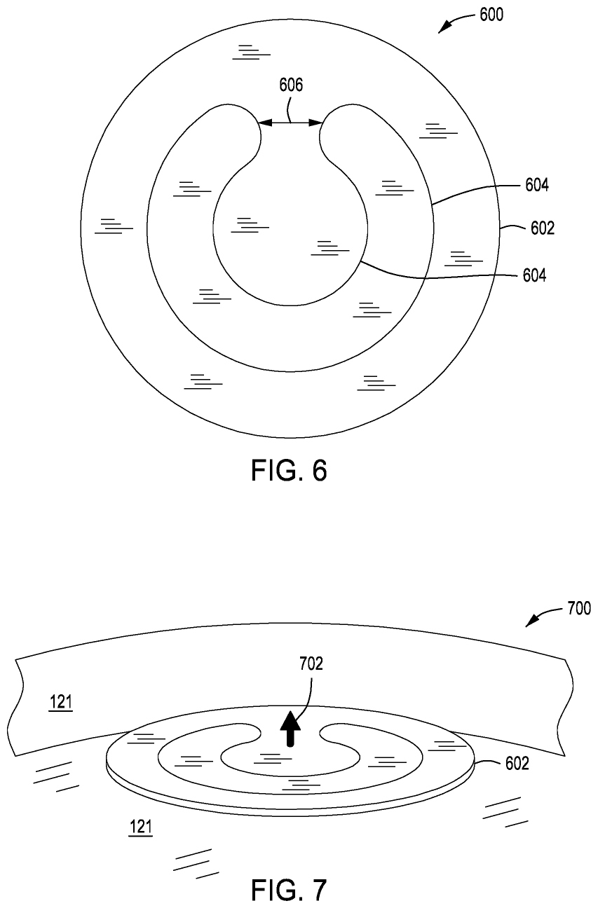

FIG. 6 is a view 600 of a target 602 showing erosion when used in conjunction with the magnetron assembly 402 of FIG. 4 in accordance with some embodiments. The target 602 is eroded more along an erosion track 604 located between the loop magnetic pole assembly 404 and the open loop magnetic pole arc assembly 410 of the magnetron assembly 402. The open loop magnetic pole arc assembly 410 of the magnetron assembly 402 creates an erosion pattern with an opening 606 that corresponds to the opening 412 of the open loop magnetic pole arc assembly 410. By adjusting the arc length 424 of the open loop magnetic pole arc assembly 410, the opening 606 of the erosion track 604 may be increased or decreased to control deposition in proximity of the opening 606.

FIG. 7 is an isometric view 700 of the target 602 when used in conjunction with the magnetron assembly 402 of FIG. 4. The opening 606 of the erosion pattern of the target 602 is oriented outwards 702 towards a wall of the shield 121 in accordance with some embodiments. The opening 606 of the erosion pattern indicates that less of the target 602 is being deposited in the proximity of the opening 606. The inventors have found that orientating the opening 606 towards the wall of the shield 121 causes less deposition of target material onto the shield, significantly reducing excess material buildup and peeling of the material on the shield 121.

While the foregoing is directed to embodiments of the present principles, other and further embodiments of the principles may be devised without departing from the basic scope thereof.

1. A magnetron assembly, comprising:
a shunt plate for supporting the magnetron assembly;
a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly; and
an open loop magnetic pole arc assembly coupled to the shunt plate surrounding at least a portion of the center magnetic pole without intersecting with the linear magnetic pole.

2. The magnetron assembly of claim 1, wherein the open loop magnetic pole arc assembly has an arc length of approximately 180 degrees to approximately 350 degrees.

3. The magnetron assembly of claim 1 is in a cathode of a process chamber.

4. The magnetron assembly of claim 3, wherein the cathode is at least one of a plurality of cathodes in a multi-cathode process chamber.

5. The magnetron assembly of claim 1 installed in a process chamber with an open portion of the open loop magnetic pole arc assembly in proximity of an outer wall of a shield within the process chamber.

6. The magnetron assembly of claim 1, wherein the loop magnetic pole assembly has an even distribution of magnets.

7. The magnetron assembly of claim 1, wherein the open loop magnetic pole arc assembly has an even distribution of magnets.

8. The magnetron assembly of claim 1, wherein at least a portion of the open loop magnetic pole arc assembly or the loop magnetic pole assembly is made of a ferromagnetic material.

9. The magnetron assembly of claim 1, wherein a first width of the open loop magnetic pole arc assembly and a second width of the loop magnetic pole are approximately equal.

10. The magnetron assembly of claim 1, wherein a first distance between the loop magnetic pole and the open loop magnetic pole arc assembly and a second distance between the open loop magnetic pole arc assembly and the center magnetic pole are approximately equal.

11. The magnetron assembly of claim 1, wherein a third distance between a first end of the open loop magnetic pole arc assembly and the linear magnetic pole and a fourth distance from a second end of the open loop magnetic pole arc assembly and the linear magnetic pole are approximately equal.

12. The magnetron assembly of claim 1, wherein the loop magnetic pole has a first constant radius about a center point of the center magnetic pole and the open loop magnetic pole arc assembly has a second constant radius about a center point of the center magnetic pole, the first constant radius greater than the second constant radius.

13. The magnetron assembly of claim 1, wherein a first distance between the loop magnetic pole and the open loop magnetic pole arc assembly and a second distance between the open loop magnetic pole arc assembly and the center magnetic pole are different.

14. An apparatus for processing semiconductors, comprising:
a process chamber with a chamber body and a top adapter assembly that form an internal volume; and
at least one cathode disposed in the top adapter assembly, the at least one cathode having a magnetron assembly configured to produce a magnetic field with a reduced magnetic field strength for a portion of the magnetic field that is in close proximity to a wall of the internal volume.

15. The apparatus of claim 14, the magnetron assembly comprising:
a shunt plate for supporting the magnetron assembly;
a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly; and
an open loop magnetic pole arc assembly coupled to the shunt plate surrounding at least a portion of the center magnetic pole without intersecting with the linear magnetic pole,
wherein the magnetron assembly is configured to be orientated such that an opening of the open loop magnetic pole arc assembly is oriented towards the wall of the internal volume.

16. The apparatus of claim 15, wherein the open loop magnetic pole arc assembly has an arc length of approximately 180 degrees to approximately 350 degrees.

17. The apparatus of claim 15, wherein a first width of the open loop magnetic pole arc assembly and a second width of the loop magnetic pole are approximately equal.

18. The apparatus of claim 15, wherein a first distance between the loop magnetic pole and the open loop magnetic pole arc assembly and a second distance between the open loop magnetic pole arc assembly and the center magnetic pole are different.

19. A cathode assembly, comprising:
a magnetron assembly configured to produce a magnetic field with a reduced magnetic field strength for a portion of the magnetic field and configured to be oriented such that the portion of the magnetic field with the reduced magnetic field strength is in close proximity to a wall of an internal volume of a process chamber when installed.

20. The cathode assembly of claim 19, wherein the magnetron assembly comprising:
a shunt plate for supporting the magnetron assembly;
a loop magnetic pole assembly coupled to the shunt plate with a loop magnetic pole, a linear magnetic pole, and a center magnetic pole, the linear magnetic pole extending from the loop magnetic pole into the center magnetic pole which is located at a center of the magnetron assembly; and
an open loop magnetic pole arc assembly coupled to the shunt plate surrounding at least a portion of the center magnetic pole without intersecting with the linear magnetic pole,
wherein the cathode assembly is configured to be installed in a process chamber such that the magnetron assembly is orientated with an opening of the open loop magnetic pole arc assembly towards an outer wall of the process chamber.
